(19) United States
(12) Patent Application Publication
(10) Pub. No.: US 2026/0223382 A1
(43) Pub. Date: Jul. 30, 2026

(54) SEMICONDUCTOR DEVICE COMPRISING A CAPACITIVE STACK AND A PILLAR AND ITS MANUFACTURING METHOD

(71) Applicant: COMMISSARIAT A L'ENERGIE ATOMIQUE ET AUX ENERGIES ALTERNATIVES, Paris (FR)

(72) Inventors: Sami OUKASSI, Grenoble cedex 09 (FR); Gaël PILLONET, Grenoble cedex 09 (FR)

(73) Assignee: COMMISSARIAT A L'ENERGIE ATOMIQUE ET AUX ENERGIES ALTERNATIVES, Paris (FR)

(21) Appl. No.: 19/137,396

(22) PCT Filed: Dec. 12, 2023
(86) PCT No.: PCT/EP2023/085395

§ 371 Date: Jun. 10, 2025

(30) Foreign Application Priority Data
Dec. 12, 2022 (FR) FR2213149

(51) Int. Cl. H10D 1/68; H10D 1/00; H10D 84/00; H10W 20/40

(52) U.S. Cl. CPC H10D 1/716; H10D 1/042; H10D 84/212; H10W 20/496

(57) ABSTRACT

The invention relates to a semiconductor device comprising: ⋅a substrate comprising at least one cavity, and ⋅a three-dimensional structure formed in the substrate comprising:—a three-dimensional capacitor comprising a capacitive stack, the capacitive stack being at least partially housed in the at least one cavity in the substrate;—a pillar extending across the thickness of the substrate from the upper face of the substrate, characterised in that the at least one cavity extends across the thickness of the substrate from the upper face of the substrate, and the capacitor is configured to define, on the upper face of the substrate, a contour of an inscribed portion, the pillar being arranged inside the inscribed portion of the substrate. The invention is applicable more particularly in the field of capacitive storage components, in particular integrated solid-state supercapacitors.

### TECHNICAL FIELD OF THE INVENTION

The present invention relates to the field of integrating microelectronic components, more specifically, for electronic products, related semiconductor products, and their manufacturing methods. The invention will apply, more specifically, in the field of capacitive storage components, in particular, integrated solid supercapacitors.

### PRIOR ART

Condensers are significant elements of integrated circuits (IC) and semiconductor devices, for example, to be used as information storage cells in memory, or energy devices. They are present in numerous electronic functions, such as processing analogue signals and energy converters. Whether they are integrated on the silicon die or outside by discrete components, they contribute significantly to the size of the system. As the available capacitor density on silicon technologies is limited to a few nF/mm², electronic circuits often use components external to the die to implement the capacitor needs in the die.

On-die silicon condensers can have different architectures. For example, MIM (Metal/Insulator/Metal) capacities, widely used in integrated circuits, comprise two metal plates with an insulator between the plates. Currently, MIM condensers are normally manufactured in the interconnecting back-end-of-line (BEOL) level. The space for integrating condensers, in particular, is often limited and superposed at the surface of the circuit, to limit the additional footprint of these capacities. Given that the capacitor of a condenser is linearly proportional to the surface of the condenser, the lack of implantation space at the BEOL limits the number of conventional MIM condensers placed in this location, which leads to an insufficient power density when the condensers are used as energy storage devices.

In searching for energy storage solutions integrated on high-performance dies, increasing the specific surface of the capacitive structure by using a three-dimensional (3D) architecture has proved to be an excellent approach, which significantly increases the capacitor density, while enabling the reduction of the die surface. The technological interest of 3D capacities resides in the fact that the capacities are stackable and comprise a surface developed in the plane (x; y) of the substrate, but also on the height/thickness z, enabling a significant space gain and a developed surface of the capacitor greater than a planar capacitor.

In the pursuit of Moore's law, current processors are becoming more and more rapid, and they are consuming more and more energy. For example, with the advent of 5G technology and three-dimensional integration for artificial intelligence and automatic learning processors, the power density remains a major challenge for condensers used as energy storage. Similar challenges in terms of capacity exist, when condensers are used as information storage devices.

For example, document US 20210305358 A1 is known, which proposes a novel optimisation approach, to meet the specifications of novel development applications. This document discloses how to make use of the level of interconnections to add a capacitive functionality. Interconnections are often perpendicular to the useful silicon surface and effectively represent a significant space. This document proposes to use the interconnection surface as one of the electrodes of the capacitor. In line with a coaxial, the second electrode of the capacitor is wound around the interconnections. The benefit is therefore to densify the capacitor value per surface unit of the useful silicon (in the horizontal plane), while benefiting from the cost reduction, as certain manufacturing steps of the capacitor can be pooled together with the manufacture of the interconnections. However, this solution has limitations, and in particular, the electrical coupling between the interconnection and the first electrode of the capacitor certainly make it possible to improve its local use, in storage filtering in line with the signal passing through the interconnexions but reduces the options for independent use of the capacitor and of the interconnection.

There is therefore the need to propose a solid ion capacitor integration solution, making it possible to meet the novel increased capacitor density needs, which avoid, at least partially, the limitations of the prior art.

### SUMMARY OF THE INVENTION

To achieve this aim, according to an embodiment, a semiconductor device is provided, comprising a substrate comprising at least one cavity, and a three-dimensional structure formed in the substrate, comprising:
a three-dimensional condenser comprising a capacitive stack, the capacitive stack being at least partially housed in the at least one cavity of the substrate,
a pillar extending along the thickness of the substrate from the upper face of said substrate,
   characterised in that the at least one cavity extends along the thickness of the substrate from the upper face of said substrate, and the three-dimensional condenser is configured to delimit, on the upper face of the substrate, a contour of an inscribed portion, the pillar being arranged in the inscribed portion of the substrate.
      According to the invention, the capacitive stack comprises a first electrode layer, an intermediate layer and a second electrode layer, and the three-dimensional structure comprises a first conform layer, comprising a first part forming the first electrode layer of the capacitive stack and a second conform part, arranged in the pillar, the first part of the second part being electrically disconnected from one another.
      Advantageously, the intermediate layer is an ion conductor dielectric material.

This device makes it possible to obtain a condenser, which has a power density and a charge density which is a lot greater than with an ion non-conductor dielectric known in the prior art.

The advantage of the device according to the invention, is to densify the capacitor value per surface unit of the useful silicon (in the horizontal plane), while benefiting from the cost reduction, as certain manufacturing steps of the three-dimensional condenser can be pooled together with the manufacture of the pillar, while preserving the independent functionalities of the condenser and of the pillar.

The invention makes it possible to benefit from the surfaces around the pillars, being able to play various roles, such as electric, thermal or mechanical, and at the same time, avoid the limitations of the solutions proposed in the prior art.

The absence of electrical coupling between the three-dimensional condenser and the pillar, while having pooled-together manufacturing steps, makes it possible to reduce the manufacturing costs.

The condenser is called three-dimensional, in that it has a three-dimensional structuration, making it possible to increase the developed surface, without increasing the silicon horizontal surface, and consequently, the associated storage capacity.

According to another aspect, the invention relates to a method for manufacturing a device such as described above, comprising
a step a) comprising the production of a three-dimensional structure comprising at least one cavity of a three-dimensional condenser, and at least one pillar in a substrate, the condenser is configured to delimit, on the upper face of the substrate, a contour of an inscribed portion, the pillar (400) being arranged in the inscribed portion of the substrate,
a step b) comprising the conform deposition of a first layer on the three-dimensional structure, i.e. in the cavity and in the pillar, as well as on the upper face of the substrate, such that a first part of the first layer forms a first layer of a capacitive stack of the condenser and that a second part of the first layer is formed in the pillar,
a step c) of filling the pillar,
a step d) of partially removing the first layer, so as to electrically disconnect the first part from the first layer and the second part from the first layer, step d) being able to be carried out before or after step c).

### BRIEF DESCRIPTION OF THE FIGURES

The aims, objectives, as well as the features and advantages of the invention will best emerge from the detailed description of an embodiment of the latter, which is illustrated by the following accompanying drawings, in which:

FIG. 1 represents a top view of a semiconductor device according to a first embodiment of the invention.

FIG. 2 represents a view along the cross-section AA of FIG. 1.

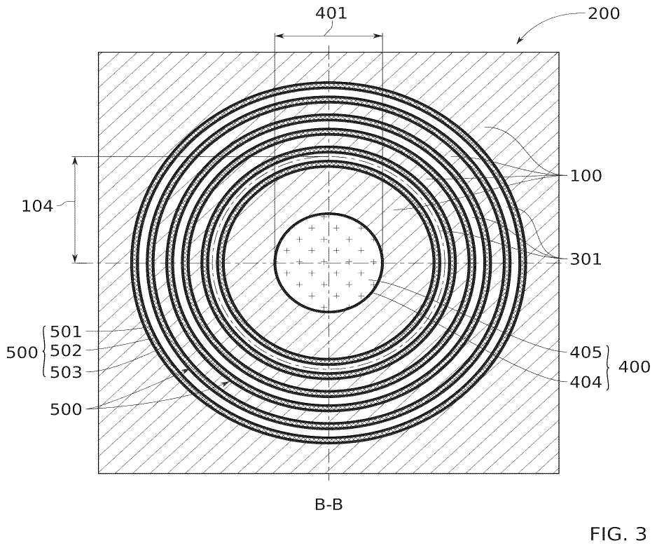

FIG. 3 represents a view along the cross-section BB of FIG. 2.

FIG. 4 represents a top view of a semiconductor device according to a second embodiment of the invention.

FIG. 5 represents a view along the cross-section CC of FIG. 4.

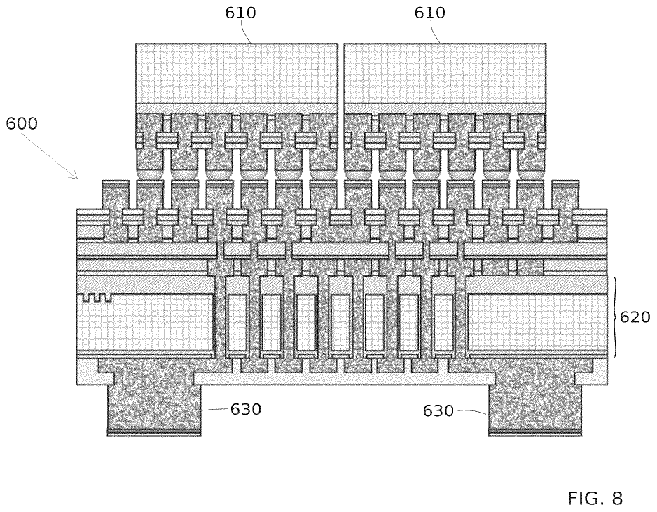

FIG. 6 represents a view along the cross-section DD of FIG. 4.

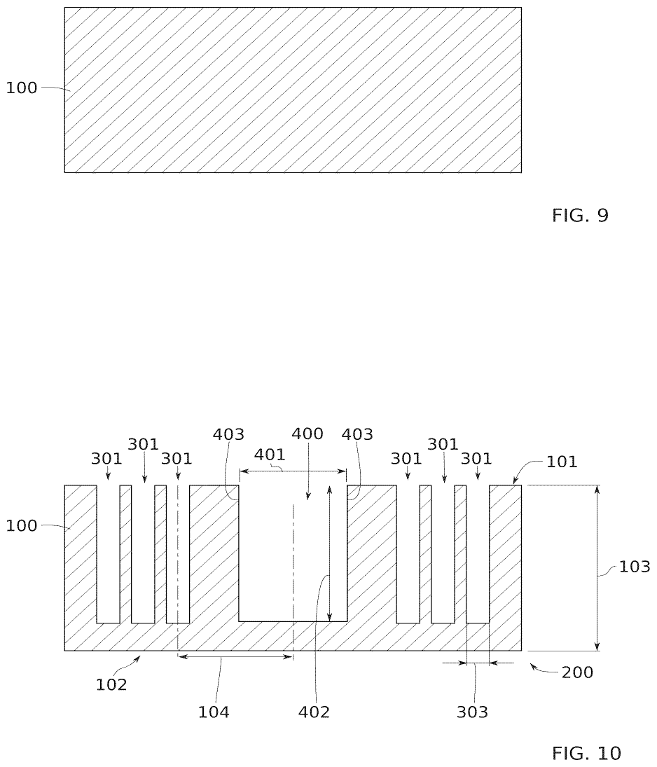

FIG. 7 represents a view along the cross-section EE of FIG. 5.

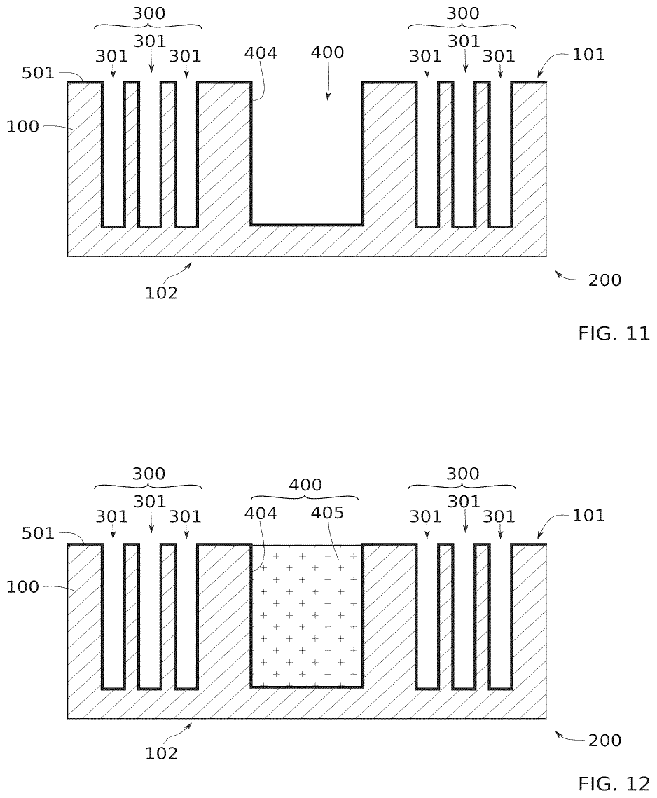

FIG. 8 represents a cross-sectional view of the semiconductor device in a complete stack.

FIGS. 9 to 15 represent the steps of the method for manufacturing a semiconductor device according to the invention.

The drawings are given as examples and are not limiting of the invention. They constitute principle schematic representations, intended to facilitate the understanding of the invention, and are not necessarily to the scale of practical applications. In particular, the layers and the size ratios of the pillar and of the cavities are not representative of reality.

### DETAILED DESCRIPTION OF THE INVENTION

Before starting a detailed review of embodiments of the invention, optional features are stated below, which can optionally be used in association or alternatively:
As an example, the ion conductive dielectric material has an ambient temperature ion conductivity at least equal to 1 μS.cm-1;
As an example, the ion conductive dielectric material has an associated activation energy less than or equal to 0.6 eV;
As an example, the pillar 400 is arranged at the centre of the inscribed portion 202;
As an example, the transverse distance 104 at the thickness 103 of the substrate between the centre of a cavity and the centre of the pillar 400 is less than or equal to 100 μm;
As an example, the transverse distance 104 at the thickness 103 of the substrate between the centre of a cavity and the centre of the pillar 400 is less than or equal to 5 μm;
As an example, at least one cavity of the condenser 300 is a trench 301;
As an example, the trench 301 is circular and arranged circular-shaped around the pillar 400;
As an example, the condenser 300 comprises at least two circular and concentric trenches 301;
As an example, at least one cavity of the condenser is a column 302;
As an example, the condenser 300 comprises a plurality of columns 302;
As an example, the plurality of columns 302 is disposed circularly around the pillar 400;
As an example, the width 401 of a pillar is 20 times greater than the width 303 of a cavity of the three-dimensional condenser 300, the widths 401, 303 being taken transversally at the thickness 103 of the substrate 100;
As an example, the three-dimensional condenser 300 comprises 2 to 20 cavities;
As an example, the pillar 400 comprises a metal material, so as to fill the pillar 400 at the upper face 101 of the substrate 100;
As an example, the metal material is different from the intermediate layer 502, such that the pillar 400 does not comprise a capacitive stack 500;
As an example, the cavity only opens onto the upper face 101 of the substrate 100;
As an example, the pillar 400 only opens onto the upper face 101 of the substrate 100;
As an example, the semiconductor device comprises an underlying layer and a layer which is overlying the substrate;
As an example, the three-dimensional structure is intended to be arranged at the interconnecting back-end-of-line (BEOL);
As an example, the three-dimensional structure is located at interconnections coupled with a processor, or behind a processor.

According to another aspect, the invention relates to a processor comprising a semiconductor device, such as described above, in which the three-dimensional structure is located at interconnections coupled with the processor, or behind the processor.
As an example, the removal of the first layer is done at the upper face 101 of the substrate 100 between the cavity and the pillar 400;
As an example, the method comprises the conform deposition of an intermediate layer, then the conform deposition of the second electrode layer;
As an example, the conform deposition of the intermediate layer is done only in the three-dimensional condenser or the conform deposition of the intermediate layer is done on the entire three-dimensional structure 200, then a step of removing the intermediate layer outside of the condenser is carried out;
As an example, the method comprises the conform deposition of the second electrode layer 503 is done only in the three-dimensional condenser 30 or the conform deposition of the second electrode layer 503 is done on the entire three-dimensional structure 200 and a step of removing the second electrode layer 503 outside of the condenser 300 is carried out forming a first part of the second layer 503 contributing to the capacitive stack;
As an example, the removal of the second electrode layer 503 is done by preserving it at the pillar 400 forming a second part of the second layer 503 on the pillar 400, the first part and the second part being electrically disconnected from one another.

By microelectronic component, this means any type of device produced with microelectronic means. These devices include, in particular, in addition to devices with a purely electronic purpose, micromechanical or electromechanical (MEMS, NEMS, etc.) devices,

By “vertical”, this means what is directed along the thickness of the stack or the substrate, i.e. along the main extension direction of the stack or of the substrate, and “horizontal”, this means what is perpendicular to the vertical. The top and the bottom being vertically opposite.

By “transverse”, this is intended as a direction perpendicular to a longitudinal direction. The longitudinal direction is intended as the thickness of the stack or of the substrate. A cross-section is a cross-section perpendicular to the longitudinal axis. A cross-section is a cross-section perpendicular to the thickness of the stack of the substrate.

The width of a cavity or of a pillar is defined as the dimension of the cavity or of the pillar transverse to the thickness.

The term “upper” used, in particular, to qualify a face of the substrate, in this case, only serves to designate a first of the two faces of the substrate (the other being the lower face), without making any assumptions on the relative position of the faces, along a vertical direction. The upper face would have thus been able to also be called front face, opposite a rear face.

The shapes or dimensions given for certain components of the present invention are only indicative and are intended as including substantially equivalent shapes and dimensions.

By a parameter “substantially equal to/greater than/less than” or “around” a given value, this means that this parameter is equal to/greater than/less than the given value, plus or minus 10%, even plus or minus 5% of this value.

It is specified that, in the scope of the present invention, the term “on”, “surmounts”, “covers”, “above” or “underlying” or “below” or their equivalents do not necessarily mean “in contact with”. For example, the deposition of a first layer on a second layer does not compulsorily mean that the two layers are directly in contact with one another, but this means that the first layer covers, at least partially, the second layer, either by being directly in contact with it, or by being separated from it by at least one other layer or at least one other element.

By a substrate, a film, a layer, a die or a protuberance “with the basis” of a material A, this means a substrate, a film, a layer, a die or a protuberance comprising this material A, and optionally other materials, for example, doping elements.

The term “coating” corresponds to a layer which is formed, in particular by modification of the underlying layer or by a deposition on this underlying layer.

By “conform”, this means a layer geometry which has, close to the manufacturing tolerances, an identical thickness despite the layer direction changes, for example, at the protuberance flanks.

The word “dielectric” corresponds to a material, the electric conductivity of which is sufficiently low in the given application to serve as an insulator.

The use of the indefinite article “a” or “an” for an element or a step does not exclude, unless mentioned otherwise, the presence of a plurality of such elements or steps.

The terms “first”, “second” and “third”, etc. are used simply as labels, and are not intended to impose numerical requirements on their objects.

By “coupled”, this means that two or more elements are in direct physical or electric contact.

The invention relates to a semiconductor device comprising a three-dimensional structure 200 formed in a substrate 100.

The basic capacitor structures are mainly stacks of layers along a direction, the thickness 103 of the substrate. In this sense, their shape is monotonous in this direction. The 3D shape, in this case, means a geometry which is more complex than a layer stack along one single direction; these can be shapes defined by one or more cavities or trenches, in which layers are present with a stack, which extends along several directions, along the surface of the cavity or of the trench, which is covered. The 3D structures also cover structures with several functionally connected cavities or trenches, typically to form parts of one same condenser 300.

The semiconductor device comprises a substrate 100.

The three-dimensional structure 200 can be implemented or produced in a substrate 100, such as a semiconductor substrate.

In an embodiment, the semiconductor substrate 100 can be a crystalline substrate, formed by using a solid silicon or a silicon-on-insulator substructure.

In other implementations, the semiconductor substrate 100 can be formed by using alternative materials, which can be combined or not with silicon, which comprise, but without being limited to, germanium, indium antimonide, lead telluride, indium arsenide, indium phosphide, gallium arsenide, indium and gallium arsenide, gallium antimonide, or other combinations of materials of the III-V group or of the IV group.

Although a few examples of materials from which the substrate 100 can be formed are described in this case, any material which can serve as a foundation on which a semiconductor device can be built falls into the spirit and the scope of the present disclosure.

The three-dimensional structure 200 is formed in the substrate 100, more specifically in a part of the substrate. It is defined below in the description, that the substrate comprises an upper face 101 opposite a lower face 102.

The three-dimensional structure 200 comprises at least one pillar 400. Preferably, the three-dimensional structure comprises a pillar 400 but can comprise several pillars 400. The pillar 400 extends along the thickness 103 of the substrate 100. The pillar 400 opens onto the upper face 101 of the substrate 100. The pillar 400 can open onto, or not, the lower face 102 of the substrate 100.

According to different embodiments, the pillar 400 is a vertical structure being able to have different functions, whether electric, thermal or packaging. As an example, the pillar 400 can be an interconnection, a via or through via (TSV for “Through Silicon Via”; there can also be through glass vias, called “TGV”), a thermal dissipation vertical structure, an encapsulation vertical structure.

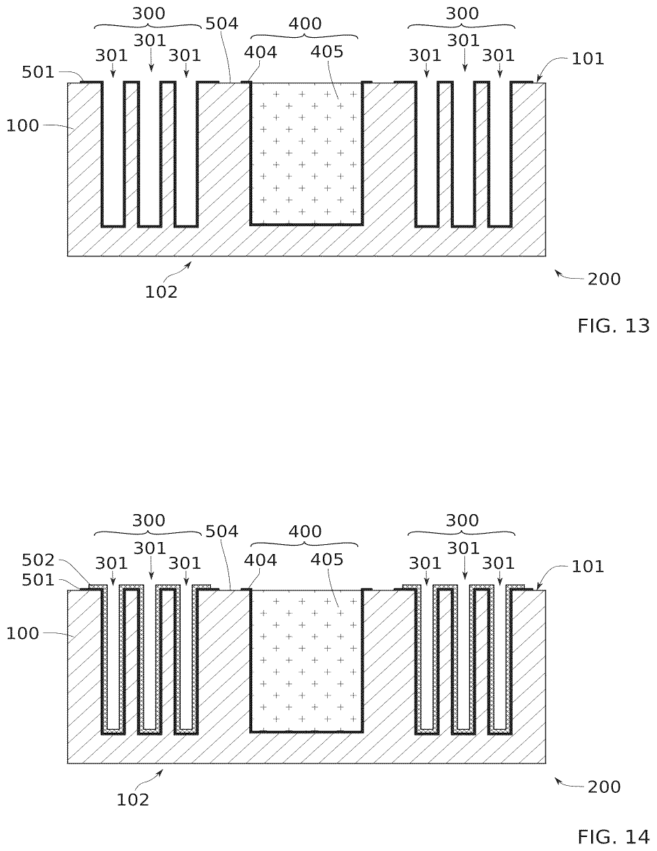

An example of an implementation is illustrated in FIG. 8, where a three-dimensional assembly 600 is found, comprising two electronic dies, for example, two processors 610, and a passive interposer 620, which enables their interconnection, and their connection to another level through copper pillars 630, thus achieving a level of redistribution of the signals. Advantageously, the three-dimensional structure 200 according to the invention is arranged at the passive interposer 620.

The pillar 400 having a depth 402 extending along the thickness 103 of the substrate 100 and a width 401 extending transversally to the thickness 103 of the substrate 100. As an example, the width 401 of the pillar 400 is greater than or equal to 2 μm.

The pillar 400 has side walls 403 having a vertical main component. Preferably, the side walls 403 of the pillar 400 are vertical, i.e. extending along the thickness 103 of the substrate 100.

According to a preferred embodiment, the pillar 400 has a cross-section transverse to the thickness of the circular-shaped substrate. Other pillar 400 shapes can be considered, such as, for example, polygonal, parallelepiped, oval.

The pillar 400 opens onto the upper face 101 of the substrate 100 and can open onto, or not, the lower face 102 of the substrate 100. According to the embodiments illustrated in the figures, the pillars 400 do not open onto the lower face 102 of the substrate 100. Subsequent steps of manufacturing the semiconductor device can however comprise the addition of an underlying layer on the lower face 102 of the substrate 100 implying that the pillar 400 opens onto the lower face 102 of the substrate 100.

The semiconductor device according to the invention comprises a three-dimensional structure 200.

The three-dimensional structure 200 is formed in a part of the substrate 100 and comprises a three-dimensional condenser 300. The three-dimensional condenser 300 comprises a capacitive stack 500 at least partially housed in a cavity formed in the substrate 100. The three-dimensional condenser 300 thus has a three-dimensional structuration, making it possible to increase the developed surface and the associated storage capacity.

Advantageously, according to the invention, the substrate 100 comprises at least one cavity. The substrate 100, more specifically the three-dimensional structure 200, can comprise up to 20 cavities, more specifically, 2 to 10 cavities. Advantageously, in the case where the substrate comprises several cavities, the cavities comprise one same capacitive stack 500, so as to optimise the capacity of the condenser 300. The description below is made in reference to a cavity but applies to all of the cavities when the three-dimensional structure 200 comprises more than one cavity. The cavity extends along the thickness 103 of the substrate 100 from the upper face 101 of said substrate 100. The cavity thus penetrates the substrate 100. Advantageously, the cavity and the pillar 400 extend along one same main direction parallel to the thickness 103 of the substrate 100.

The cavity opens onto the upper face 101 of the substrate 100 and advantageously does not open onto the lower face 102 of the substrate 100, so as to enable the arrangement of the capacitive stack 500 on a substrate surface which is as large as possible.

Below in the description, the three-dimensional condenser 300 can be simply called condenser 300.

According to the invention, the condenser 300 is configured to delimit, on the upper face 101 of the substrate 100, a contour 201 of an inscribed portion 202.

The contour 201 can be of various shapes, such as, for example, circular, ovoid, parallelepiped, polygonal.

Advantageously, according to the invention, the inscribed portion 202 comprises at least one pillar 400. Preferably, the pillar 400 is arranged in the inscribed portion 202 defined by the condenser 300.

According to a preferred embodiment, the pillar 400 is arranged at the centre of the inscribed portion 202. More specifically, the centre of the pillar 400 corresponds to the centre of the inscribed portion 202.

Advantageously, the three-dimensional structure 200 comprises a first conform layer comprising a first part forming the first electrode layer 501 of the capacitive stack 500 and a second part 404 arranged in the pillar 400, more specifically covering the side walls 403 of the pillar 400. The first electrode layer 501 and the second part 404 are advantageously identical, in particular, since they are formed preferably at the same time by one single deposition of a first layer. Preferably, the first part forming the first electrode layer 501 and the second part 404 arranged in the pillar 400 are electrically disconnected from one another. The electric disconnection of the first part forming the first electrode layer 501 and of the second part 404 arranged in the pillar 400 is done advantageously by partial removal 504 of the first layer, in particular, on the upper face 101 of the substrate 100.

The arrangement of the three-dimensional condenser 300 in a three-dimensional structure 200 comprising a pillar 400 enables a space gain by using a substrate 100 part conventionally used, while enabling a pooling together of the steps, in particular, the deposition of the first layer, without involving a functional link between the condenser 300 and the pillar 400.

According to a preferred embodiment, the width 401 of the pillar 400 is at least 20 times greater than the width 303 of a cavity, preferably 50 times greater than the width 303 of a cavity.

According to a first embodiment, the cavity of the condenser 300 is a trench 301. By “trench” 301, this means a cavity in the substrate 100 having a dimension length greater than its width 303. The length being understood as the direction transverse to the thickness and to the width. Preferably, the ratio between the length and the width is greater than or equal to 2, preferably greater than or equal to 20. As an example, the trench 301 has a depth, i.e. a dimension extending along a direction parallel to the thickness 103 of around 20 μm.

According to this first embodiment, the trench 301 is rectilinear or curved. The rectilinear trench 301 can be a straight line extending along one single direction or extending along several directions and thus forming a broken line. The curved trench 301 can be a continuous curve along one single direction or extending along several directions and thus forming a curved line.

According to a preferred option of this first embodiment, the condenser 300 can comprise a trench 301 itself defining the contour 201 of the inscribed portion 202. The trench 301 is thus closed on itself, the ends of the trench 302 join one another. According to the shape of the trench 301, the inscribed portion 202 can be of any variable shape. Preferably, the trench 301 is, for example, circular, or also polygonal or parallelepiped.

In this option, the pillar 400 is at the centre of the inscribed portion 202 and the trench 301 forms the contour 200 of the inscribed portion 202.

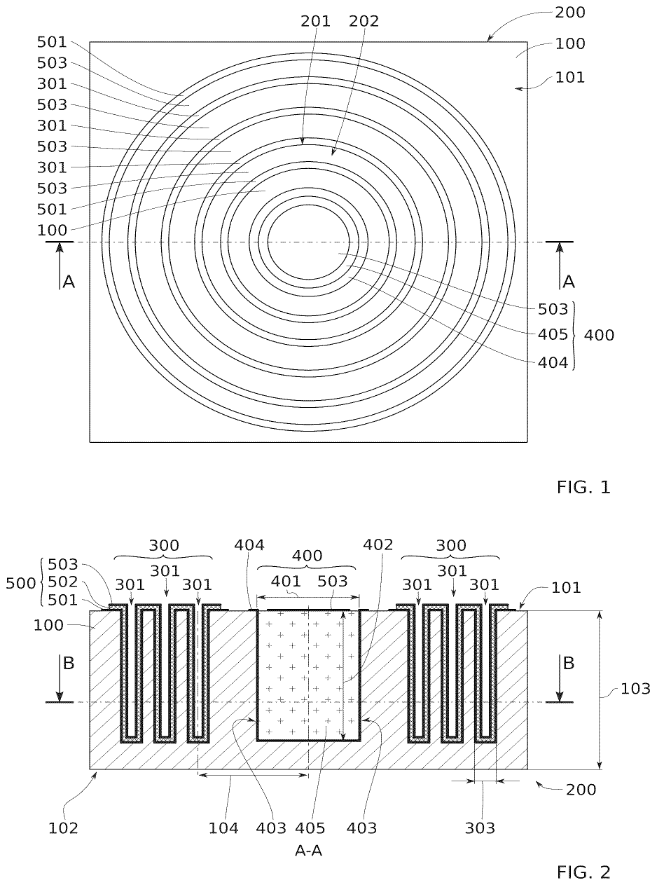

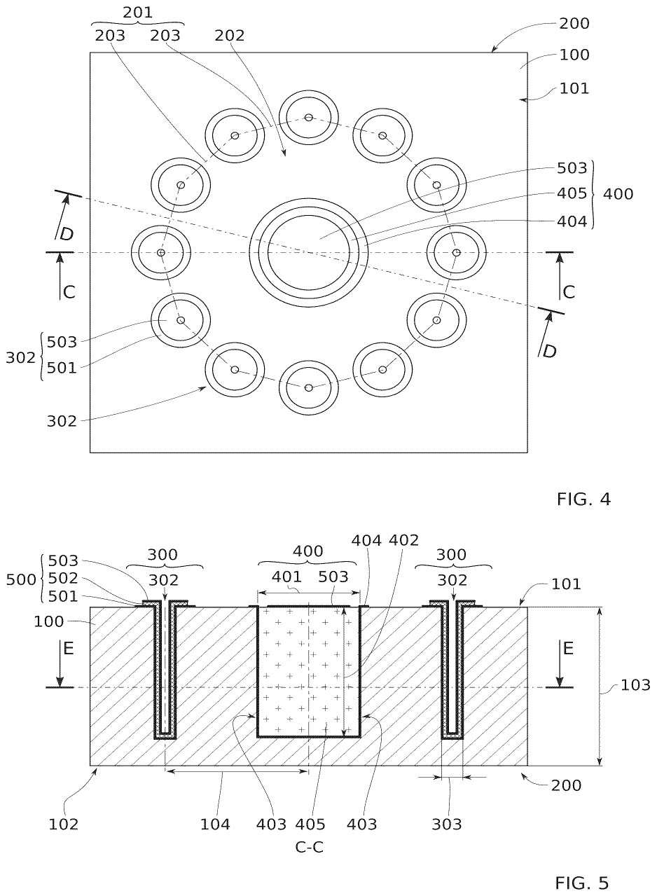

The condenser 300 can comprise several cavities and, in particular, several trenches 301. According to the preferred option, the condenser 300 comprises several trenches 301 closed on themselves and concentric. Preferably, the trenches 301 are circular as illustrated in FIGS. 1 and 3. The trenches 301 advantageously comprise one same capacitive stack 500, so as to increase the surface of the capacitor of the condenser 300.

According to a second embodiment, the cavity of the condenser 300 is a column 302. By “column”, this means a cavity in the substrate 100 having a dimension length which is substantially equivalent to its width. Preferably, the ratio between the length and the width is around 1. As an example, the length and the width are 10 μm and the depth is around 20 μm.

Each column 302 has a cross-section with circular, ovoid, parallelepiped, polygonal thickness. All the columns 302 can, or not, have one same cross-sectional shape.

Advantageously, in this second embodiment, the condenser 300 comprises at least three columns 302. The columns 302 are thus advantageously arranged, so as to define a contour 201 of an inscribed portion 202.

Advantageously, the contour 201 of the inscribed portion 202 is formalised by all of the lines 203 connecting the successive columns 302 to one another. Preferably, the contour 201 is formed by all of the lines 203 connecting the columns 302 closest to the pillar 400.

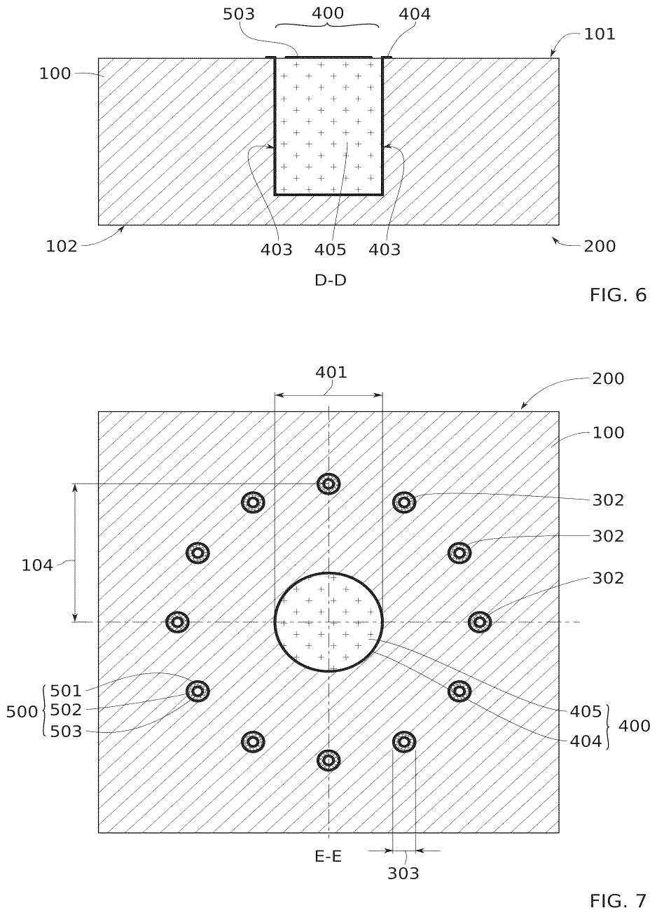

The columns 302 are advantageously arranged around the pillar 400, so as to form an advantageously circular contour 201, such as illustrated in FIG. 4.

As a preferred example, the distance 104 transverse to the thickness 103 separating the centre of the pillar 400 from the centre of a cavity is less than or equal to 100 μm.

As a preferred example, the distance 104 transverse to the thickness 103 separating the centre of the pillar 400 from the centre of a cavity is greater than or equal to 5 μm.

According to a third embodiment, the first embodiment and the second embodiment are combined. The condenser 300 comprises at least one trench 301 and at least one column 302.

Whatever the embodiment described above, the condenser 300 comprises a capacitive stack 500 comprising a first electrode layer 501 advantageously formed at least by the first part of a first layer 501, an intermediate layer 502 and a second electrode layer 503.

Preferably, the first electrode layer 501 covers the side walls of at least one cavity, preferably all of the cavities of the three-dimensional structure 200 and of the upper face 101 of the substrate 100 exposed between the cavities. As a preferred example, the first electrode layer 501 is chosen from among TiN, TaN, W, Ni, Pt, Ru materials.

Preferably, the intermediate layer 502 is a dielectric ion material and covers the first electrode layer 501. The intermediate layer 502 can be a solid-state electrolyte. As a preferred example, the dielectric is an ion conductor. As an example, the ion conductor has an increase ambient temperature ion conductivity (preferably between 20° C. and 25° C., preferably at 25° C.), at least 1 μS.cm-1, and advantageously which also has a low associated activation energy, generally less than 0.6 eV. The intermediate layer 502 can comprise Al₂O₃, HfO₂, ZrO₂, TiO₂, Nb₂O₅, Ta₂O₅, SrTiOx, BaTiOx, Ga₂O₃, Y₂O₃, a rare earth oxide, a solid state electrolyte, a glass electrolyte, a ceramic electrolyte, LiPON, an ion antiperovskite, Li₃ClO, a doped Li(3-2x)DxClO where D is a divalent cationic dopant, hafnium silicate, zirconium silicate, hafnium dioxide, hafnium zirconate, zirconium dioxide, aluminium oxide, titanium oxide, silicon nitride, carbon-doped silicon nitride, silicon carbide and nitride hafnium silicate, a dielectric material with high k, or an alloy of these.

The dielectric ion material intermediate layer 502 makes it possible to obtain a condenser which has a power density and a charge density which are a lot greater than with an ion non-conductive dielectric, known in the prior art.

Preferably, the second electrode layer 503 covers the intermediate layer 502. As a preferred example, the second electrode layer 503 is TiN, TaN, W, Ni, Pt, Ru.

The first electrode layer 501, the second electrode layer 503, and the second part 404 can comprise W, Mo, Ti, Ta, Al, TaN, TiN, TiC, WN, MoN, MoC, Co, Ni, Cu, Ru, Pd, Pt, Ir, IrOx, graphene, MnO₂, Li, RuOx, ITO, SrRuOx, a metal oxide, graphitic carbon, an alkaline metal, a low-working-function metal, a transition metal oxide, a Co oxide, LiCoO₂, NaCoO₂, a transition metal dichalcogenide, a spinel oxide, LiMn₂O₄, LiNiMnO₄, a conductive polymer or a conductive metal.

Advantageously, the first electrode layer 501 overflows at its ends on the upper face 101 relative to the intermediate layer 502 and to the second electrode layer 503, so as to enable the connection of the first electrode layer 501 and of the second electrode layer 503 separately.

According to an option, either of the two from among the first electrode layer 501 and the second electrode layer 503 is an ion intercalation electrode. In the case where the first electrode layer 501 and the second electrode layer 503 are both intercalation electrodes, the semiconductor device comprises a microbattery.

Advantageously, the pillar 400 comprises the second part 404 of the first conform layer covering the side walls 403. According to an option, the pillar 400 comprises a metal material 405 filling all of the remaining volume and ensuring a levelling with the upper face 101 of the substrate 100. The presence of the second part 404 of the first conform layer in the pillar 400 can have an interest, as an interdiffusion barrier between the substrate 100 and the metal material 405, or also an ion diffusion barrier from the metal material 405 to the substrate 100. The second part 404 of the first conform layer acts as a barrier to the diffusion between the substrate 100 and the metal material 405, or also to an additional chemical barrier to improve the encapsulation of the components. Preferably, the metal material 405 is different from the intermediate layer 502 of the capacitive stack. Preferably, the metal material 405 is different from the first electrode layer 501, and preferably from the second electrode layer 503. The metal material 405 is chosen according to the aim of the pillar 400 being preferably different from electronic conduction, and being, for example, thermal dissipation, encapsulation, packaging, etc.

Preferably, the pillar 400 does not comprise a capacitive stack 500.

According to an option, the pillar 400 comprises a part of the second electrode layer 503. A part of the second electrode layer 503 is arranged on the metal material 405, so as to at least partially cover the metal material 405. This part of the second electrode layer 503 makes it possible to facilitate/optimise the electric, thermal or mechanical contact between the metal material 405 and the following levels. As an example, this part of the second electrode layer 503 is identical to the second electrode layer 503, described above in reference to the capacitive stack.

By “inscribed”, this means that the condenser 300 has a three-dimensional shape, which extends to the upper face 101 of the substrate, by delimiting for this upper face 101, two surface parts: a part inside the condenser 300 which is that inscribed, and an outer part. The shape of the condenser 300 itself provides an inner edge (this is the case for a circular trench 301), or a cavity placement border (this is the case, if the condenser 300 is formed with several cavities, for example, of the column 302 type, which surrounds an inner part according to a profile, regular or not, of delimitation of this surface). By joining the edges of these cavities spaced apart around the inscribed surface, the shape of this border is revealed. The cavities are thus such as poles delimiting a surface of the ground, barriers joining the poles revealing the shape of this surface, which is the inscribed surface. The contour of this surface, formed by the condenser, can therefore be continuous (as in the case of a trench with a closed contour, for example, circular) or discrete as in the case of via-shaped cavities.

According to an option, the semiconductor device according to the invention is produced on the rear face of a CMOS technology.

According to an option, the semiconductor device comprises an underlying layer, such as, for example, a substrate comprising a transistor and/or an overlying layer.

According to an option, the semiconductor device is made of an interconnecting back-end-of-line (BEOL).

An example of an integration of a semiconductor device according to the invention is illustrated in FIG. 8.

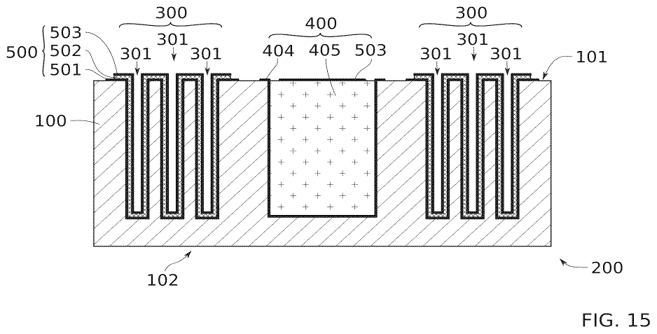

According to another aspect, the invention relates to a method for manufacturing a semiconductor device such as described above. The different steps of the method are illustrated in FIGS. 9 to 15.

According to an aspect, the method for manufacturing a semiconductor device comprising the following steps of:
forming at least one cavity of the condenser 300 in the substrate 100, and extending along the thickness 103 of the substrate 100 from the upper face 101 of the substrate 100,
forming of a pillar 400 in the substrate 100 and extending along the thickness 103 of the substrate 100 from the upper face 101 of said substrate 100, characterised in that the condenser 300 is configured to delimit, on the upper face 101 of the substrate 100, a contour 201 of an inscribed portion (202), the pillar 400 being arranged in the inscribed portion 202 of the substrate 100.

As an example, the method comprises the following steps of:
conformly depositing a first layer on the surface of the three-dimensional structure 200, such that a first part of the first layer forms a first layer 501 of the capacitive stack 500 of the condenser 300 and that a second part 404 of the first layer is formed in the pillar 400, and,
removing a part of the first layer 500 on the upper face 101 of the substrate 100 between the pillar 400 and the capacitive stack 500, such that the pillar 400 and the capacitive stack 500 are not electrically connected.

The manufacturing method starts as illustrated in FIG. 9 by the presence of the substrate 100.

The manufacturing method advantageously comprises a step a) comprising the production of at least one cavity and of at least one pillar 400 in a substrate 100. This first production step is carried out by a plasma-type etching step, more commonly called deep reactive ion etching or DRIE and known by a person skilled in the art. Advantageously, the arrangement of the at least one cavity and of the pillar 400 is defined, such that the cavity defines a contour of an inscribed portion with the pillar arranged in the inscribed portion. The semiconductor device obtained from step a) is illustrated in FIG. 10.

Following step a), the method comprises a step b) comprising the conform deposition of a first layer on the three-dimensional structure 200, i.e. in the cavity and in the pillar, as well as on the upper face 101 of the substrate 100. The conform deposition is achieved by conventional methods known to a person skilled in the art, such as: chemical vapour deposition (CVD), or atomic layer deposition (ALD). The semiconductor device obtained from step b) is illustrated in FIG. 11.

Preferably, the method then comprises a step c) of filling the pillar 400. The filling is done by conventional methods known to a person skilled in the art, such as: electrochemical deposition or electroless deposition. The semiconductor device obtained from step c) is illustrated in FIG. 12.

Preferably, the method comprises a step d) of advantageously partially removing 504 the first layer, so as to electrically disconnect a first part from the first layer 501, and a second part 404 from the first layer. Preferably, the removal of the first layer is done at the upper face 101 of the substrate 100, preferably between the cavity and the pillar 400. The removal is done by conventional methods known to a person skilled in the art, such as: chemical etching or plasma etching, both coupled with photolithography to define patterns. The semiconductor device obtained from step d) is illustrated in FIG. 13.

This step d) can be carried out before or after step c).

Preferably, the method then comprises successive steps to produce the continuation of the capacitive stack 500. The method comprises the conform deposition of the intermediate layer 502, then the conform deposition of second electrode layer 503. The production of the capacitive stack 500 is done by conventional methods known to a person skilled in the art, such as: atomic layer deposition or ALD.

According to an option, the conform deposition of the intermediate layer 502 is done only such as illustrated in FIG. 14, or the conform deposition of the intermediate layer 502 is done on the entire three-dimensional structure 200 and the method comprises a step of removing the intermediate layer 502 outside of the condenser 300.

In the same way, the conform deposition of the second electrode layer 503 is done only such as illustrated in FIG. 15, or the conform deposition of the second electrode layer 503 is done on the entire three-dimensional structure 200 and the method comprises a step of removing the second electrode layer 503 outside of the condenser 300 and advantageously of the pillar 400 forming a first part of the second layer 503 contributing to the capacitive stack and a second part of the second layer 503 on the pillar 400. The first part and the second part are electrically disconnected from one another.

The invention is not limited to the embodiments described above and extends to all the embodiments covered by the invention.

### LIST OF REFERENCES

100. Substrate
101. Upper face
102. Lower face
103. Thickness
104. Transverse distance
200. Three-dimensional structure
201. Contour
202. Inscribed portion
203. Line
300. Three-dimensional condenser
301. Trench
302. Columns
303. Width of the cavity
400. Pillar
401. Width of the pillar
402. Depth of the pillar
403. Side walls
404. Second part of the first layer
405. Metal
500. Capacitive stack
501. First electrode layer
502. Intermediate layer
503. Second layer
600. Three-dimensional assembly
610. Processor
620. Passive interposer
630. Copper pillars cm 1. A semiconductor device comprising:
a substrate comprising at least one cavity, and
a three-dimensional structure formed in the substrate comprising:
   i. a three-dimensional condenser comprising a capacitive stack the capacitive stack being at least partially housed in the at least one cavity of the substrate and
   ii. a pillar extending along a thickness of the substrate from an upper face of the substrate, wherein
the at least one cavity extends along the thickness of the substrate from the upper face of said substrate, and
the three-dimensional condenser is configured to delimit, on the upper face of the substrate, a contour of an inscribed portion, the pillar being arranged in the inscribed portion of the substrate, and
the capacitive stack comprises a first electrode layer, an intermediate layer and a second electrode layer,
the three-dimensional structure comprises a first conform layer comprising a first part forming the first electrode layer of the capacitive stack and a second part arranged in the pillar, the first part and the second part being electrically disconnected from one another, and
the intermediate layer is an ion conductive dielectric material.

2. The semiconductor device according to claim 1, wherein the ion conductive dielectric material has an ambient temperature ion conductivity at least equal to 1 μS.cm⁻¹.

3. The semiconductor device according to claim 1, wherein the ion conductive dielectric material has an associated activation energy less than or equal to 0.6 eV.

4. The semiconductor device according to claim 1, wherein the pillar is arranged at a centre of the inscribed portion.

5. The semiconductor device according to claim 1, wherein a transverse distance at the thickness of the substrate between a centre of a cavity and a centre of the pillar is less than or equal to 100 μm.

6. The semiconductor device according to claim 1, wherein a transverse distance at the thickness of the substrate between a centre of a cavity and a centre of the pillar is less than or equal to 5 μm.

7. The semiconductor device according to claim 1, wherein the condenser a trench.

8. The semiconductor device according to claim 7, wherein the trench is circular and arranged around the pillar.

9. The semiconductor device according to claim 7, wherein the condenser comprises at least two circular and concentric trenches.

10. The semiconductor device according to claim 1, wherein the condenser comprises at least one cavity being a column.

11. The semiconductor device according to claim 10, wherein the condenser comprises a plurality of columns.

12. The semiconductor device according to claim 11, wherein the plurality of columns is disposed circularly around the pillar.

13. The semiconductor device according to claim 1, wherein the pillar comprises a metal material, so as to fill the pillar at the upper face of the substrate.

14. The semiconductor device according to claim 13, wherein the metal material is different from the intermediate layer, such that the pillar does not comprise a capacitive stack.

15. A processor comprising a semiconductor device according to claim 1, wherein the three-dimensional structure is located at interconnections coupled with the processor, or behind the processor.

16. A method for manufacturing a device according to claim 1, comprising
producing the three-dimensional structure comprising the three-dimensional condenser having at least one cavity and at least one pillar in the substrate, the condenser being configured to delimit, on the upper face of the substrate, a contour of an inscribed portion, the pillar being arranged in the inscribed portion of the substrate,
conformally depositing the first conform layer in the cavity of the three-dimensional structure, in the pillar and on the upper face of the substrate, such that the first part of the first conform layer forms a first layer of a capacitive stack of the condenser and that the second part of the first conform layer is formed in the pillar,
filling the pillar,
partially removing the first layer, so as to electrically disconnect the first part from the first layer and the second part from the first layer, before or after filling the pillar.

17. The method according to claim 16, wherein partially removing the first layer is done at the upper face of the substrate between the at least one cavity of the condenser and the pillar.

18. The method according to claim 16, comprising conformally depositing the intermediate layer, then conformally depositing the second electrode layer.

19. The method according to claim 18, wherein conformally depositing the intermediate layer is done only in the three-dimensional condenser.

20. The method according to claim 18, comprising conformally depositing the second electrode layer is done only in the three-dimensional condenser.

21. The method according to claim 18, comprising partially removing the second electrode layer to form a first portion on the intermediate layer and a second portion on the pillar, the first portion and the second portion being electrically disconnected from one another.
